(19) United States
(12) Patent Application Publication
(10) Pub. No.: US 2015/0212425 A1
(43) Pub. Date: Jul. 30, 2015

(54) Quantitative Reticle Distortion Measurement System

(71) Applicants: ASML HOLDING N.V., Veldhoven (NL); ASML NETHERLANDS B.V., Veldhoven (NL)

(72) Inventors: Michael Andrew Chieda, Stratford, CT (US); Stephen Roux, New Fairfield, CT (US); Teun Peterus Adrianus De Wilt, Eindhoven (NL); Igor Matheus Petronella Aarts, Chester, NY (US)

(21) Appl. No.: 14/430,021

(22) PCT Filed: Aug. 27, 2013
(86) PCT No.: PCT/EP2013/067673

§ 371 Date: Mar. 20, 2015

Related U.S. Application Data
(60) Provisional application No. 61/707,123, filed on Sep. 28, 2012.

(51) Int. Cl. G03F 7/20; G01B 11/25; G01D 5/347

(52) U.S. Cl. CPC G03F 7/70191; G01D 5/347; G01B 11/2513; G03F 7/70716

(57) ABSTRACT

A lithographic apparatus includes an illumination system configured to condition a radiation beam, a support constructed to hold a patterning device, the patterning device being capable of imparting the radiation beam with a pattern in its cross-section to form a patterned radiation beam, a substrate table constructed to hold a substrate, and a projection system configured to project the patterned radiation beam onto a target portion of the substrate. The lithographic apparatus further includes an encoder head designed to scan over a surface of the patterning device to determine a distortion in a first direction along a length of the patterning device and a distortion in a second direction substantially perpendicular to the surface of the patterning device.

### CROSS-REFERENCE TO RELATED APPLICATIONS

This application claims the benefit of U.S. provisional application 61/707,123, which was filed on 28 Sep. 2012, and which is incorporated herein in its entirety by reference.

### BACKGROUND

1. Field of the Invention

The present invention relates to a lithographic apparatus and measuring reticle distortions

2. Background Art

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

A number of factors can degrade optical performance of lithography tools. Manufacturing errors in the projection optics mirrors, as well as thermally induced deformations in their illuminated regions during operation, can produce optical aberrations which will degrade image quality at the wafer. Image placement errors (distortion) can also occur. Since the reticle illumination is non-telecentric, changes in reticle height (caused for example by non-flatness of the reticle) can also produce distortion at the wafer.

Indirect measurements of the reticle distortion are typically performed and involve observing changes to an exposed pattern on a test wafer. Such measurement techniques are time consuming and are unable to separate effects due to reticle deformation from other contributing effects in the system. Furthermore, these measurements are not carried out in real time during an exposure using the reticle.

Some example systems for directly measuring reticle deformation include retrodiffractive interferometry, phase shifting speckle interferometry, and optical interferometry. However, each of these techniques is only able to measure either in-plane distortion or out-of-plane distortion, but not both simultaneously. Furthermore, techniques such as retrodiffractive interferometry require bulky equipment not suited for use within the space constraints of many lithographic systems.

### SUMMARY

Therefore, what is presented is a system and method to directly measure reticle distortion in a quantitative manner, and to provide substantially simultaneous in-plane and out-of-plane distortion measurements.

According to an aspect of the present invention, there is provided a lithographic apparatus that includes an illumination system configured to condition a radiation beam, a support constructed to hold a patterning device, the patterning device being capable of imparting the radiation beam with a pattern in its cross-section to form a patterned radiation beam and the patterning device including a plurality of features, a substrate table constructed to hold a substrate, and a projection system configured to project the patterned radiation beam onto a target portion of the substrate. The lithographic apparatus further includes an encoder head configured to scan over a surface of the patterning device to determine a first displacement of the plurality of features relative to a first displacement of the support in a first direction along a length of the patterning device and to determine a second displacement of the plurality of features relative to a second displacement of the support in a second direction substantially perpendicular to the surface of the patterning device to generate a distortion map of the surface of the patterning device based on the determined first and second displacements of the plurality of features.

According to another aspect of the present invention, there is provided an apparatus having a support, a first and second encoder head, and a processing device. The support is configured to hold an object where the support and the object each include a plurality of features. The first encoder head is configured to scan over a surface of the object and measure a first parameter indicative of a distortion associated with the plurality of features on the object in a first direction along a length of the object and in a second direction substantially perpendicular to the surface of the object. The second encoder head is configured to measure a second parameter associated with the plurality of features on the support. The processing device is configured to generate a distortion map of the surface of the object based on the measured first parameter on the object and the measured second parameter on the support.

According to another aspect of the present invention, there is provided a method that includes measuring a first parameter indicative of a distortion associated with a first plurality of features on a surface of an object in a first direction along a length of the object and in a second direction substantially perpendicular to the surface of the object and measuring a second parameter associated with a second plurality of features on a surface of a support configured to hold the object. The method further includes generating a distortion map of the surface of the object based on the measured first parameter and the measured second parameter.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 depicts a lithographic apparatus, according to an embodiment of the invention.

FIG. 2 depicts a side view within the lithographic apparatus showing a reticle and a measurement system, according to an embodiment.

FIG. 3 depicts a view looking at the surface of the reticle with the measurement system aimed at the surface, according to an embodiment.

FIG. 4 depicts a model of estimated signal output based on a level of reticle distortion according to an embodiment.

FIG. 5 depicts an example method, according to an embodiment.

FIG. 6 depicts another example method, according to an embodiment.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

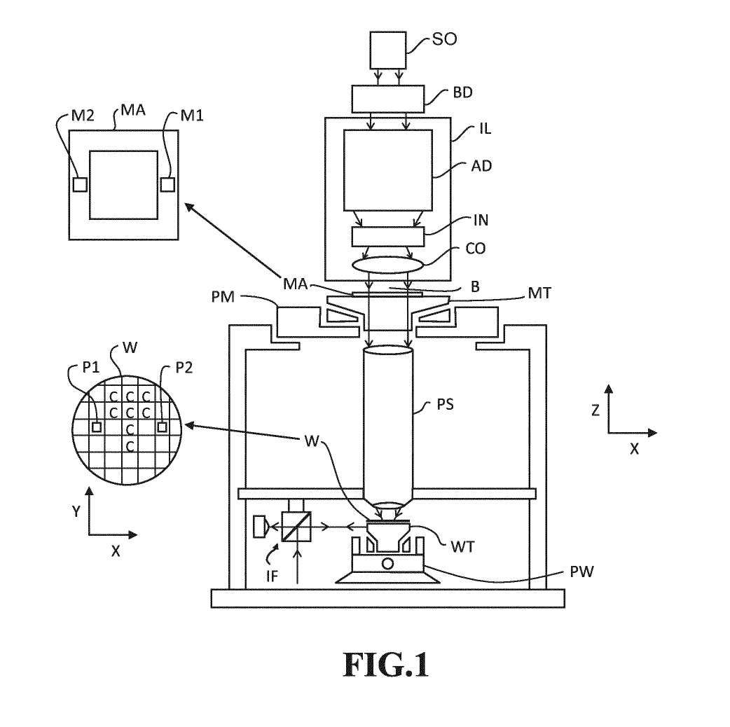

FIG. 1 schematically shows a lithographic apparatus LAP including a source collector module SO according to an embodiment of the invention. The apparatus includes: an illumination system (illuminator) IL configured to condition a radiation beam B (e.g., EUV radiation); a support structure (e.g., a mask table) MT constructed to support a patterning device (e.g., a mask or a reticle) MA and connected to a first positioner PM configured to accurately position the patterning device; a substrate table (e.g., a wafer table) WT constructed to hold a substrate (e.g., a resist-coated wafer) W and connected to a second positioner PW configured to accurately position the substrate; and a projection system (e.g., a reflective projection system) PS configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e., bears the weight of, the patterning device. It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable mirror array of a type as referred to above, or employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross section.

The radiation beam B is incident on the patterning device (e.g., mask MA), which is held on the support structure (e.g., mask table MT), and is patterned by the patterning device. Having traversed the mask MA, the radiation beam B passes through the projection system PS, which focuses the beam onto a target portion C of the substrate W. With the aid of the second positioner PW and position sensor IF (e.g., an interferometric device, linear encoder or capacitive sensor), the substrate table WT can be moved accurately, e.g., so as to position different target portions C in the path of the radiation beam B. Similarly, the first positioner PM and another position sensor (which is not explicitly depicted in FIG. 1) can be used to accurately position the mask MA with respect to the path of the radiation beam B, e.g., after mechanical retrieval from a mask library, or during a scan. In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:

1. In step mode, the mask table MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the mask table MT and the substrate table WT are scanned synchronously while a pattern imparted to the radiation beam is projected onto a target portion C (i.e., a single dynamic exposure). The velocity and direction of the substrate table WT relative to the mask table MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the mask table MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

The present invention relates to the quantitative determination of reticle deformation using an in-situ measurement system. The measurement system includes a set of at least two encoders for measuring both features present on the surface of the reticle and features present on the chuck holding the reticle. In one embodiment, the encoder heads and/or reticle are capable of translating in directions parallel to the surface of the reticle to allow for a map to be generated of the entire reticle surface. By measuring the difference between the displacement of the features on the reticle surface as compared to the features on the chuck using the encoder heads, a quantitative determination of reticle deformation can be calculated. A more localized amount of distortion may be further calculated by taking the gradient of the position difference. Further details of the system are provided below in reference to the figures.

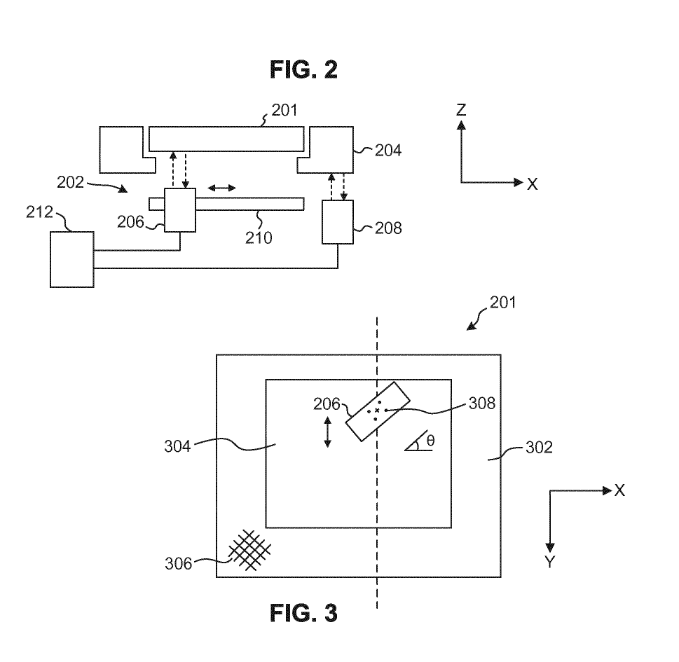

FIG. 2 illustrates a side view of a reticle 201 along with a measurement system 202, according to an embodiment. In one example, measurement system 202 includes a first encoder head 206 and a second encoder head 208. First encoder head 206 is positioned to measure a phase change associated with a target that is indicative of a displacement of reticle 201, while second encoder head is positioned to measure a phase change associated with a target that is indicative of a displacement of chuck 204. By determining differences in the displacement determined between reticle 201 and chuck 204, a distortion or warpage of reticle 201 may be calculated. It should be understood that other encoder heads beyond the two illustrated may be used as well for measuring phase change on either reticle 201 or chuck 204. For example, more than one encoder head may be used to measure various portions of chuck 204. In another example, at least two encoder heads may each be positioned at various orientations for measuring a phase change associated with a target that is indicative of a displacement of either reticle 201 or chuck 204. Chuck 204 may be designed to hold reticle 201 as illustrated from the sides and/or around the lower edge of reticle 201. Chuck 204 may also be designed to hold reticle 201 via, for example, an applied vacuum pressure or electrostatic potential to clamp reticle 201 to chuck 204.

First encoder head 206 may be a two-dimensional or three-dimensional encoder head. A two-dimensional encoder head is capable of measuring a phase change associated with a target that is indicative of a displacement along two different axis to provide in-plane and out-of-plane distortion measurement, for example, along a Z-axis and along a X-axis (or Y-axis). A three-dimensional encoder head is capable of measuring phase changes along all three axes to provide in-plane and out-of-plane distortion measurement along the X, Y, and Z-axis. Second encoder head 208 may be a one-dimensional or two-dimensional encoder head. In another example, second encoder head 208 is a three-dimensional encoder head. Second encoder head 208 may be the exact same model as first encoder head 206, however, this is not necessary for operation, but could be preferable to yield even more accurate signal comparisons between the encoder heads. First encoder head 206 and second encoder head 208 may use various signaling techniques to measure features on reticle 201 and chuck 204 respectively. These techniques may include optical, magnetic, capacitive, inductive, etc. For ease of explanation, the description herein will assume that the encoder heads use optical signals.

In an embodiment, first encoder head 206 may be attached to a linear drive mechanism 210 for translating first encoder head 206 across the surface of reticle 201. For example, first encoder head 206 may be moved along the X-axis as illustrated in FIG. 2. In another example, first encoder head 206 may be moved along the Y-axis or be attached to a test stage with allowable movement within the X-Y plane. Additionally, reticle 201 may be translated via the movement of chuck 204. For example, chuck 204 may be operable to move along all three axes, X, Y, and Z. Each of first encoder head 206 and chuck 204 may be operable to move in all 6 degrees of freedom. Alternatively, the first encoder head 206 may be fixed relative to the reticle 201. For example, the first encoder head 206 may be mounted on an optical system such as a lens top.

Many movement variations are possible to perform scans of the surface of reticle 201. In one example, reticle 201 and chuck 204 translate along the Y-axis, while first encoder head 206 and second encoder head 208 remain stationary. Thus, a single Y-scan pass has been performed. Then, first encoder head 206 may make incremental shifts along the X-axis while reticle 201 and chuck 204 continue to translate along the Y-axis. In this way, the surface of reticle 201 may be mapped via sequential scans along the Y-axis. It should be understood that the specific axis mentioned in these examples are arbitrary and that each component of the system could just as easily be designed to translate or make incremental shifts in either the X, Y, or Z direction.

During the translation of reticle 201 and chuck 204, first encoder head 206 and second encoder head 208 are measuring a phase change associated with a plurality of features on both reticle 201 and chuck 204 respectively. These plurality of features, e.g. measurement targets, may include an ordered array of features, such as diffraction gratings, a 2-D diffraction grid, or any other pattern that in some way is consistent on both reticle 201 and chuck 204. In one example, encoder heads 206 and 208 measure the phase change between the feature patterns on both reticle 201 and chuck 204 to determine relative displacements of both reticle 201 and chuck 204.

For example, an encoder head may be configured to scan over a surface of the patterning device to determine a first displacement of the plurality of features relative to a first displacement of the support in a first direction along a length of the patterning device and to determine a second displacement of the plurality of features relative to a second displacement of the support in a second direction substantially perpendicular to the surface of the patterning device. And a distortion map of the surface of the patterning device may be generated based on the determined first and second displacements of the plurality of features.

In an embodiment, encoder heads 206 and 208 are capable of measuring the distance traveled with picometer resolution. In an embodiment, if reticle 201 is undistorted, then the two encoder heads 206 and 208 measurements will indicate substantially the same feature displacement during a linear scan. However, if reticle 201 is distorted, then encoder heads 206 and 208 measurements will indicate different displacements between the features of reticle 201 and the features of chuck 204, since the line spacing of the features on reticle 201 has changed due to the distortion.

The measured data from each of encoder heads 206 and 208 of measurement system 202 is received by a processing device 212, according to an embodiment. Processing device 212 may comprise one or more hardware microprocessors or processor cores. Processing device 212 may be included within the lithographic apparatus or as part of an external computing unit. Any signal transmission technique may be employed for sending data between encoder heads 206 and 208 and processing device 212, including electrical, optical, RF, etc., and may be in analog or digital format.

In one example, processing device 212 receives data from both first encoder head 206 and second encoder head 208, and generates a distortion map of the surface of reticle 201 based on the received data, according to an embodiment. For example, processing device 212 performs a difference calculation between the received data from first encoder head 206 and the received data from second encoder head 208. The difference between the data outputs from the two encoder heads 206 and 208 is a quantitative measurement of the accumulated (e.g., along the scan direction) reticle distortion. In another example, the localized amount of distortion is determined by taking the gradient of the position difference. The generated distortion map may be used to refine analytic and software models of reticle heating and distortion, evaluating new designs and materials for reticles, clamps, clamp cooling, chucks, etc. The system may also be used to investigate distortion effects other than reticle heating such as clamp distortions and repeatability, effects of particles trapped between the clamp and reticle, and micro-slipping, among others.

FIG. 3 illustrates a view looking up at an underside of reticle 201, according to an embodiment. First encoder head 206 is also shown scanning the surface of reticle 201.

Reticle 201 may be a test reticle that includes a plurality of features, such as 2-D grid 306, over substantially an entire surface of reticle 201. A test reticle may be placed first within the lithographic apparatus to determine the amount of distortion imposed upon the reticle so that corrections may be made to the exposure when the real reticle containing the pattern to be exposed is used thereafter. However, in another embodiment, reticle 201 may include an active area 304 that includes patterned features to be exposed, and an outer region 302 where features such as, for example, 2-D grid 306 are used for determining distortion. In this way, distortion measurements may be made on the same reticle that is being used for exposing the wafer within the lithographic apparatus. The data collected from reticle distortion measurements from within outer region 302 may be extrapolated using models and/or previously collected data to generate a distortion map across substantially the entire surface of reticle 201.

In an embodiment, first encoder head 206 is rotated about the Z-axis at an angle θ as illustrated in FIG. 3. In one example, the angle θ is substantially a 45 degree angle about the Z-axis with respect to either the X or Y axis. Other angles may be contemplated as well and the invention should not be limited by such. By adjusting the angle of first encoder head 206, displacements along both the X and Y axis may be measured. A plurality of optical beams 308 are produced by first encoder head 206 and impinge upon the surface of reticle 201 along an axis substantially not normal to the surface, according to an embodiment.

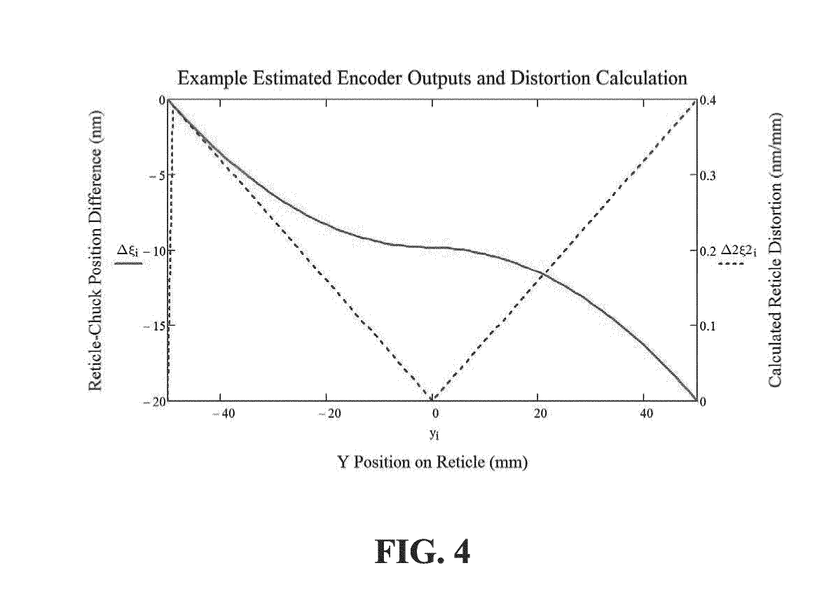

FIG. 4 illustrates output from a simulated model of reticle distortion. The accumulated position error is illustrated due to a grid distortion of a test reticle modeled as in-plane expansion due to, for example, reticle heating. The calculated reticle distortion (illustrated as the dotted line) with regard to Y-axis position along the reticle is determined by taking the derivative of the difference between the reticle and chuck positions (illustrated as the solid line). As such, even though a difference may exist between the measured positions of the reticle and chuck, if that difference remains constant, than the local distortion is substantially zero (as is observed near the center of the reticle where Y-position is zero in this simulated model.)

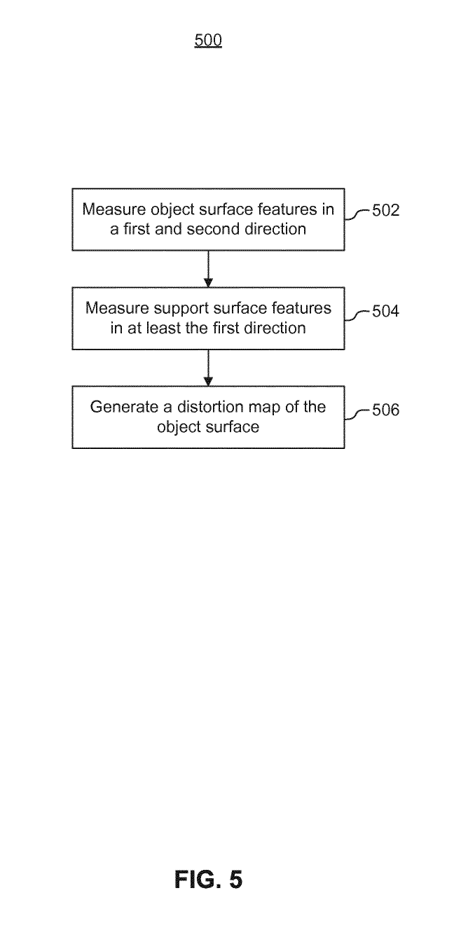

FIG. 5 illustrates a flowchart depicting a method 500 for measuring distortion of an object surface, according to an embodiment. The various steps of method 500 may be carried out using various embodiments of measuring system 202. It is to be appreciated that method 500 may not include all operations shown, or perform the operations in the order shown.

Method 500 begins at step 502 where the object surface is measured via, for example, an encoder head, in a first direction and a second direction. The first direction may be along a length of the object while the second direction may be substantially perpendicular to the surface of the object or visa-versa. The surface measurement may be designed to determine displacement via a plurality of features on the surface of the object.

Method 500 continues with step 504 where a surface of a support is measured via, for example, an encoder head, along at least the first direction. Step 504 may occur simultaneously with step 502 such that measurement of both the object and support occur simultaneously as both the object and support are moved in, for example, the first direction. The surface measurement of the support may be designed to determine displacement via a plurality of features on the surface of the support.

At step 506, a distortion map is generated of the surface of the object based on the measured parameters associated with the plurality of features on both the object and the support. The distortion map may be generated by a processing device that receives data related to the measured plurality of features of both the object and the support. In one example, the difference between the measured displacements of the object and support is calculated to determine the distortion map. Furthermore, localized distortion may be calculated by taking the gradient of the position difference.

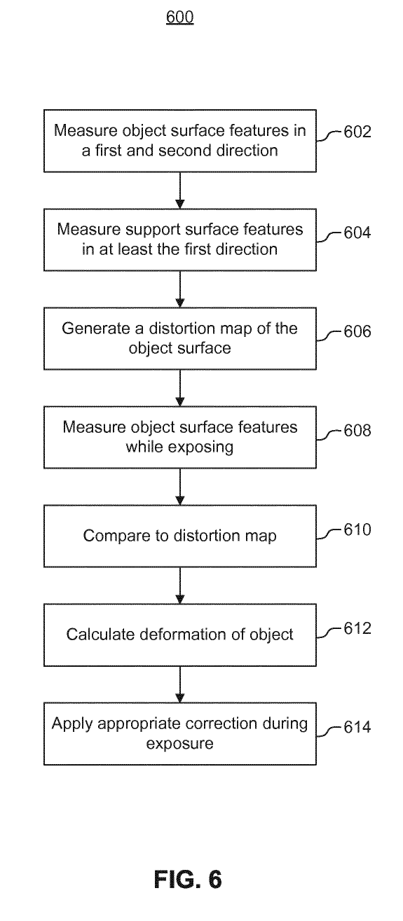

FIG. 6 illustrates another flowchart depicting a method 600 for measuring and correcting distortion of an object surface, according to an embodiment. The various steps of method 600 may be carried out using various embodiments of measuring system 202. It is to be appreciated that method 600 may not include all operations shown, or perform the operations in the order shown.

Method 600 begins with steps 602, 604 and 606, which are similar to steps 502, 504, and 506 as previously described. As such, their description will not be repeated here.

After the generation of a distortion map, method 600 continues with step 608 where the surface of the object is measured again during an exposure using the object. For example, a reticle surface may be measured by an encoder head within a lithographic apparatus while the heat generated from the impinging electromagnetic radiation during an exposure causes further distortion or deformation of the reticle surface. Thus, the measurement may be performed while the reticle is in use and provide a snapshot of the surface distortion at a particular point in time during its use.

At step 610, the measured distortion from step 608 is compared to the distortion map generated in step 606. In an example, the comparison provides data regarding how much the object deformation has changed before and after the exposure of light to the object surface.

At step 612, the object deformation is calculated based on the comparison performed in step 610. The calculation may be performed by a processing device that has access to the stored distortion map and receives the distortion measurements of the object surface.

At step 614, a correction is applied to the object during the exposure of light to the object surface. The correction may involve applying forces to various portions of the object to mechanically correct the surface distortion. The forces may be applied via actuators positioned around the object. In another example, the correction may involve driving various mirrors and/or lenses of the projection system in a lithographic apparatus to compensate for the measured surface distortions of the object. The mirrors and/or lenses may be driven by coupled actuators, according to an embodiment.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g., semiconductor memory, magnetic or optical disk) having such a computer program stored therein.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A lithographic apparatus comprising:
an illumination system configured to condition a radiation beam;
a support constructed to hold a patterning device, the patterning device being capable of imparting the radiation beam with a pattern in its cross-section to form a patterned radiation beam, the patterning device including a first plurality of features and the support including a second plurality of features;
a substrate table constructed to hold a substrate;
a projection system configured to project the patterned radiation beam onto a target portion of the substrate;
an encoder head configured to scan over a surface of the patterning device to determine a first displacement associated with the first plurality of features on the patterning device relative to a first displacement associated with the second plurality of features on the support in a first direction along a length of the patterning device, and to determine a second displacement associated with the first plurality of features on the patterning device relative to a second displacement associated with the second plurality of features on the support in a second direction substantially perpendicular to the surface of the patterning device; and
a processing device for generating a distortion map of the surface of the patterning device based on the first and second displacements associated with the first plurality of features on the patterning device and at least one of the first and second displacements associated with the second plurality of features on the support.

2. The apparatus according to claim 1, wherein the encoder head comprises a 2-D or a 3-D encoder head.

3. The apparatus according to claim 2, wherein the 2-D or 3-D encoder head is oriented at a substantially 45 degree angle to a scan direction.

4. The apparatus according to claim 1, wherein the encoder head is configured to scan over the surface of the patterning device in the first direction and the support is configured to translate the patterning device in a third direction perpendicular to the first and second directions.

5. The apparatus according to claim 1, further comprising a processing device configured to calculate a distortion in at least the first direction using the first plurality of features.

6. The apparatus according to claim 1, wherein the first plurality of features comprises an ordered array of features.

7. The apparatus according to claim 1, wherein the first plurality of features are patterned around an active area of the patterning device.

8. The apparatus according to claim 1, further comprising another encoder head configured to measure at least one displacement of the second plurality of features on the support.

9. The apparatus according to claim 8, wherein the second plurality of features comprises an ordered array of features.

10. The apparatus according to claim 8, wherein the processing device is configured to:
receive a first set of data associated with the first plurality of features;
receive a second set of data associated with the second plurality of features; and
generate the distortion map of the surface of the patterning device based on a difference between the first and second sets of data.

11. The apparatus according to claim 10, wherein the second set of data is used as reference data in response to generation of the distortion map.

12. The apparatus according to claim 10, wherein the processing device is further configured to generate a localized distortion map by taking the gradient of a difference in positions associated with the first and second sets of data.

13. The apparatus according to claim 10, wherein the generated distortion map provides a quantitative evaluation of distortion across at least a portion of the surface of the patterning device.

14. The apparatus according to claim 1, wherein the encoder head is further configured to produce one or more optical beams directed towards the surface of the patterning device.

15. An apparatus comprising:
a support constructed to hold an object, wherein the object includes a first plurality of features and the support includes a second plurality of features;
a first encoder head configured to scan over a surface of the object and to measure a first parameter indicative of a distortion associated with the first plurality of features in a first direction along a length of the object and in a second direction substantially perpendicular to the surface of the object;
a second encoder head configured to measure a second parameter associated with the second plurality of features on the support; and
a processing device configured to generate a distortion map of the surface of the object based on the measured first parameter and the measured second parameter.

16. The apparatus according to claim 15, wherein the first encoder head comprises a 2-D or a 3-D encoder head.

17. The apparatus according to claim 16, wherein the 2-D or 3-D encoder head is oriented at a substantially 45 degree angle to a scan direction.

18. The apparatus according to claim 15, wherein the first encoder head is configured to scan over the surface of the object in the first direction and the support is configured to translate the object in a third direction perpendicular to the first and second directions.

19. The apparatus according to claim 15, wherein the first and second plurality of features include an ordered array of features.

20. The apparatus according to claim 15, wherein the processing device is further configured to:
receive a first set of data associated with the first plurality of features;
receive a second set of data associated with the second plurality of features; and
generate the distortion map of the object surface based on a difference between the first and second sets of data.

21. The apparatus according to claim 20, wherein the second set of data is used as reference data in response to generation of the distortion map.

22. The apparatus according to claim 20, wherein the processing device is further configured to generate a localized distortion map by taking the gradient of a difference in positions associated with the first and second sets of data.

23. The apparatus according to claim 20, wherein the generated distortion map provides a quantitative evaluation of distortion across at least a portion of the surface of the object.

24. The apparatus according to claim 15, wherein the first encoder head is further configured to produce one or more optical beams directed towards the surface of the object.

25. A method comprising:
measuring, using a first encoder head, a first parameter indicative of a distortion associated with a first plurality of features on a surface of an object in a first direction along a length of the object and in a second direction substantially perpendicular to the surface of the object;
measuring, using a second encoder head, a second parameter associated with a second plurality of features on a surface of a support that is configured to hold the object;
generating, using a processing device, a distortion map of the surface of the object based on the measured first parameter and the measured second parameter.

26. The method of claim 25, further comprising:
receiving a first set of data associated with the first plurality of features;
receiving a second set of data associated with the second plurality of features;
generating the distortion map of the object surface based on a difference between the first and second sets of data;
calculating, using the processing device, a deformation of the surface of the object based on the distortion map; and
correcting the deformation of the surface of the object via one or more actuators.

27. A reticle stage comprising:
a support configured to hold an object, wherein the object includes a first measurement target, and the support includes a second measurement target;
a first encoder head configured to scan over a surface of the object to determine a first displacement in a first direction along a length of the object based on the first measurement target and in a second direction substantially perpendicular to the surface of the object;
a second encoder head configured to scan over a surface of the support to determine a second displacement based on the second measurement target; and
a processing device configured to generate a distortion map indicative of the object being distorted based on the determined first and second displacement measurements.

28. The reticle stage according to claim 27, wherein the first encoder head comprises a 2-D encoder head and the first measurement target is a diffraction grating comprising a plurality of lines having a spacing.

29. The reticle stage according to claim 28, wherein the distortion map indicates that the object is distorted if the first and second encoder heads indicate different distances traveled due to a change in the line spacing of the diffraction grating on the object.

30. The reticle stage according to claim 27, wherein a difference between the first and second displacement measurements indicates a quantitative evaluation of a distortion of the object.

31. The reticle stage according to claim 27, wherein the processing device is further configured to generate a localized distortion map by taking the gradient of a difference in positions associated with the first and second displacement measurements.

32. The reticle stage according to claim 27, wherein the object is a patterning device and the support is a reticle chuck configured to hold the patterning device.
